(19) United States
(12) Patent Application Publication
(10) Pub. No.: US 2026/0305095 A1
(43) Pub. Date: Oct. 1, 2026

(54) DISPLAY DEVICE AND ELECTRONIC DEVICE COMPRISING THE SAME

(71) Applicant: Samsung Display Co., Ltd., Yongin-Si (KR)

(72) Inventor: DAEGEUN LEE, Yongin-si (KR)

(21) Appl. No.: 19/530,904

(22) Filed: Feb. 5, 2026

(30) Foreign Application Priority Data
Apr. 1, 2025 (KR) 10-2025-0042137

(51) Int. Cl. H10K 59/131

(52) U.S. Cl. CPC H10K 59/131

(57) ABSTRACT

A display device according to an embodiment includes a substrate comprising a display area and a non-display area, a pad portion positioned on the non-display area and comprising a plurality of electrode pads, and indicators positioned along a periphery of the pad portion on the non-display area and specifying positions of each of the plurality of electrode pads.

### CROSS-REFERENCE TO RELATED APPLICATIONS

This application claims priority to and the benefit of Korean Patent Application No. 10-2025-0042137, filed on Apr. 01, 2025, the entire contents of which are incorporated herein by reference.

### BACKGROUND

### 1. Field

The present disclosure relates to a display device and an electronic device comprising the same.

### 2. Description of the Related Art

As the information society develops, demands for display devices for displaying images are increasing in various forms. For example, display devices are applied to various electronic devices such as smartphones, digital cameras, laptop computers, navigation systems, and smart televisions. The display device may be a flat panel display device such as a Liquid Crystal Display Device, a Field Emission Display Device, or an Organic Light Emitting Display Device. Among these flat panel display devices, a light emitting display device includes light emitting elements in which each of the pixels of the display panel can emit light by itself, so that images can be displayed without a backlight unit that provides light to the display panel.

The Chip-On Glass (COG) method or Chip-On Plastic (COP) method, in which a driving chip is mounted on a glass substrate or a plastic substrate, has a simple structure and can increase the ratio of the display area in the display panel, so it is widely used. Also, the Chip-On Silicon (COS) method, in which a driving chip is mounted on a silicon wafer substrate, is used for ultra-small, high-resolution displays such as OLEDoS (OLED on Silicon).

### SUMMARY

Embodiments relate to a display device and an electronic device comprising the same, and are for specifying positions of a plurality of electrode pads that are not visible from the front by patterning indicators around a pad portion.

A display device according to an embodiment may include a substrate including a display area and a non-display area, a pad portion positioned on the non-display area and including a plurality of electrode pads, and indicators positioned along a periphery of the pad portion on the non-display area and specifying positions of the plurality of electrode pads.

In an embodiment, the plurality of electrode pads are arranged in an x-axis direction and a y-axis direction crossing each other, the indicators include first indicators disposed in the x-axis direction and second indicators disposed in the y-axis direction, and the plurality of electrode pads may be aligned with the first indicators and the second indicators.

In an embodiment, positions of the plurality of the electrode pads may be points where lines extending from the first indicators in a y-axis direction and lines extending from the second indicators in an x-axis direction meet.

In an embodiment, the plurality of electrode pads have rows arranged in an x-axis direction and columns arranged in a y-axis direction, the plurality of electrode pads positioned in a same row are aligned with a same second indicator, and the plurality of electrode pads positioned in a same column may be aligned with a same first indicator.

In an embodiment, the plurality of electrode pads have rows arranged in an x-axis direction and columns arranged in a y-axis direction, the plurality of electrode pads positioned in a same row are aligned with a same second indicator, and the plurality of electrode pads positioned in a same column may be aligned with different first indicators.

In an embodiment, the first indicators and the second indicators may each include a marker (M) and an identifier (N).

In an embodiment, the identifier is characters for distinguishing a position of each of the plurality of electrode pads and may include at least one of an alphabetic character and a number.

In an embodiment, the identifier may be positioned adjacent to an end of the marker.

In an embodiment, the marker may include at least one of a dot and an indication line.

In an embodiment, the marker includes the indication line, indication lines of the first indicators extend in a y-axis direction and may be aligned with reference points of the plurality of electrode pads in the y-axis direction, and indication lines of the second indicators extend in an x-axis direction and may be aligned with reference points of the plurality of electrode pads in the x-axis direction.

In an embodiment, the reference point may be a center of the plurality of electrode pads.

In an embodiment, at least one of the indication lines of the first indicators and the indication lines of the second indicators includes an auxiliary line connected to an end of the at least one of the indication lines and perpendicular to the at least one of the indication lines, and the identifier may be positioned along the auxiliary line.

In an embodiment, the marker may include a dot positioned at an end of the indication line.

In an embodiment, the marker includes a dot, dots of the first indicators may be aligned with centers of the plurality of electrode pads in a y-axis direction, and dots of the second indicators may be aligned with centers of the plurality of electrode pads in an x-axis direction.

In an embodiment, the first indicators may be positioned above or below the pad portion in the y-axis direction, and the second indicators may be positioned to the left or right of the pad portion in the x-axis direction.

In an embodiment, the indicators may be in a raised or recessed form with respect to a front surface of the substrate.

In an embodiment, the substrate may be a silicon wafer substrate.

In an embodiment, the display device may further include an integrated circuit positioned on the pad portion and coupled to the plurality of electrode pads.

An electronic device according to an embodiment includes a display device, a processor, a memory, and a power module, wherein the display device includes a substrate including a display area and a non-display area, a pad portion positioned on the non-display area and including a plurality of electrode pads, and indicators positioned along a periphery of the pad portion on the non-display area and specifying positions of the plurality of electrode pads.

In an embodiment, the plurality of electrode pads may be arranged in an x-axis direction and a y-axis direction crossing each other, the indicators may include first indicators disposed in the x-axis direction and second indicators disposed in the y-axis direction, and the plurality of electrode pads may be aligned with the first indicators and the second indicators.

According to an embodiment, positions of a plurality of electrode pads may be specified by patterning indicators for specifying positions of the plurality of electrode pads around a pad portion.

For instance, even in the case that the substrate and the integrated circuit of the display device are opaque, the position of a defective pad may be specified by the indicators to easily perform destructive analysis.

### BRIEF DESCRIPTION OF THE DRAWINGS

FIG. 1 is a plan view of a display device according to an embodiment.

FIG. 2 is a cross-sectional view taken along line II-II' of FIG. 1.

FIG. 3 is a cross-sectional view taken along line III-III' of FIG. 1.

FIG. 4 is an enlarged view of area A of FIG. 1 according to an embodiment.

FIG. 5 is an enlarged view of area A of FIG. 1 according to an embodiment.

FIG. 6 is an enlarged view of area A of FIG. 1 according to an embodiment.

FIG. 7 is an enlarged view of area A of FIG. 1 according to an embodiment.

FIG. 8 is a block diagram of an electronic device according to an embodiment.

FIGS. 9 to 11 are schematic diagrams of electronic devices according to various embodiments.

### DETAILED DESCRIPTION

Hereinafter, various embodiments of the present disclosure will be described in detail with reference to the accompanying drawings so that those skilled in the art to which the present disclosure pertains can easily practice them. The present disclosure may be implemented in various different forms and is not limited to the embodiments described herein.

To clearly describe the present disclosure, parts irrelevant to the description have been omitted, and the same reference numerals are given to the same or similar components throughout the specification.

In addition, the size and thickness of each component shown in the drawings are arbitrarily shown for convenience of description, so the present disclosure is not necessarily limited to what is shown. In the drawings, the thickness is enlarged to clearly express various layers and regions. And in the drawings, for convenience of description, the thickness of some layers and regions is exaggerated.

Also, in case that a part such as a layer, layer, region, or plate is said to be "on" or "over" another part, this includes not only the case where it is "directly on" the other part but also the case where there is another part in between. Conversely, in case that a part is said to be "directly on" another part, it means that there is no other part in between. Also, being "on" or "over" a reference part means being positioned above or below the reference part, and does not necessarily mean being positioned "on" or "over" in the direction opposite to gravity.

Also, throughout the specification, in case that a part is said to "include" a certain component, this means that it may further include other components rather than excluding other components unless specifically stated otherwise.

Also, throughout the specification, "in a plan view" means viewing the target part from above, and "in a cross-sectional view" means viewing a cross section of the target part cut vertically from the side.

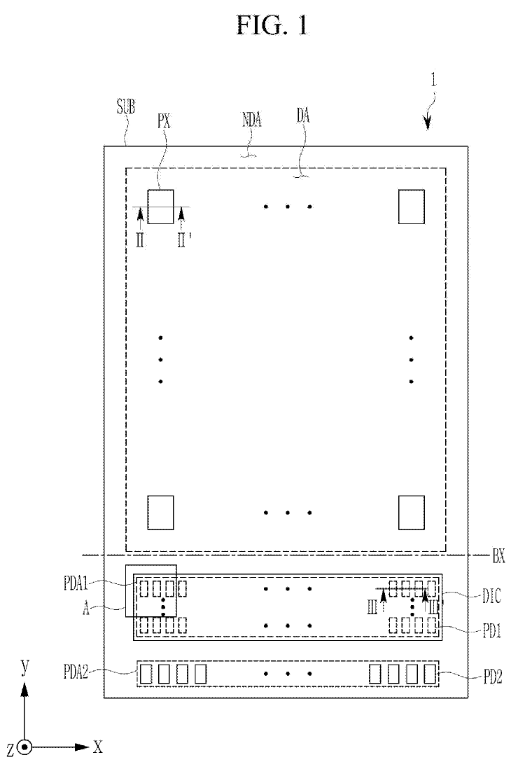

Hereinafter, a structure of a display device according to an embodiment will be described with reference to FIGS. 1 to 3.

FIG. 1 is a plan view of a display device according to an embodiment.

Referring to FIG. 1, a display device 1 according to an embodiment may include a substrate SUB extending along an x-axis direction x and a y-axis direction y that cross each other.

The substrate SUB may include a display area DA and a non-display area NDA positioned around the display area DA. The display area DA is an area where pixels PX are disposed and an image is displayed, and the non-display area NDA is an area where an image is not displayed. The non-display area NDA may be defined as an area where wirings and electronic components for driving the pixels PX are disposed.

A plurality of pixels PX may be arranged in a matrix form along an x-axis direction x and a y-axis direction y that cross each other. In an embodiment of the present disclosure, each of the pixels PX may display at least one of red color, green color, or blue. In an embodiment of the present disclosure, the pixels PX may display at least one of white color, cyan color, or magenta color. Each of the pixels PX includes a light emitting element, and any one of the colors may be displayed by the light emitting element.

Depending on the type of pixels PX, the display device 1 may be a liquid crystal display device or a light emitting display device such as an organic light emitting display device. Hereinafter, in the present embodiment, the display device 1 is described as an organic light emitting display device, but is not limited thereto.

The non-display area NDA may include a first pad portion PDA1 and a second pad portion PDA2. The first pad portion PDA1 may include a plurality of first electrode pads PD1. The second pad portion PDA2 may include a plurality of second electrode pads PD2.

An integrated circuit DIC may be disposed on the first pad portion PDA1. The integrated circuit DIC may overlap the first pad portion PDA1 in a plan view. The integrated circuit DIC may be mounted on the first pad portion PDA1 in a Chip-on Silicon (COS) manner. Without being limited thereto, the integrated circuit DIC may be mounted in a Chip-On Glass (COG) manner or a Chip-on Plastic (COP) manner.

The integrated circuit DIC may be a source driver integrated circuit that applies a data voltage to the display area DA, a scan driver integrated circuit that applies a gate voltage to the display area DA, or an integrated driver integrated circuit in which both a source driver and a scan driver are integrated. In addition, FIG. 1 shows a case in which one integrated circuit DIC is mounted on the first pad portion PDA1, but according to an embodiment, a plurality of integrated circuits may be mounted.

A bending axis BX may be defined between the first pad portion PDA1 and the display area DA. The display device 1 may be bent based on the bending axis BX.

The display device 1 may include a printed circuit board electrically connected to the second pad portion PDA2. The printed circuit board may be connected to a control device for controlling the operation of the display device 1.

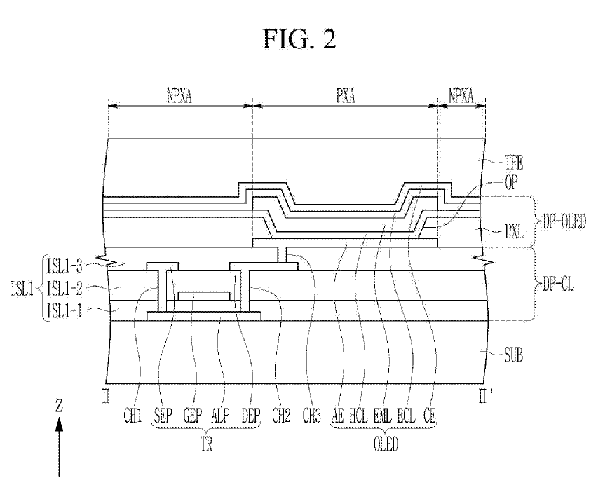

FIG. 2 shows a part of the display area DA and is a cross-sectional view taken along line II-II' of FIG. 1.

Referring to FIG. 2, the display device 1 includes a substrate SUB, a first layer DP-CL, a second layer DP-OLED, and a thin film encapsulation layer TFE. The first layer DP-CL includes a plurality of conductive layers and a plurality of insulating layers, and the second layer DP-OLED may include a plurality of conductive layers and a plurality of functional organic layers.

The display area DA (see FIG. 1) may include a light emitting area PXA and a non-light emitting area NPXA. The light emitting area PXA is an area where light generated by the light emitting element OLED is emitted in a z-axis direction z. The non-light emitting area NPXA is adjacent to the light emitting area PXA and is an area where light generated by the light emitting element OLED is not emitted in the z-axis direction z.

A semiconductor layer ALP of a transistor TR may be positioned on the substrate SUB. The semiconductor layer ALP may include amorphous silicon formed at a low temperature. In an embodiment, the semiconductor layer ALP may include a metal oxide semiconductor. Although not separately illustrated, a barrier layer or a buffer layer may be disposed between the substrate SUB and the semiconductor layer ALP.

A first insulating member ISL1 covering the transistor TR may be positioned on the substrate SUB. The first insulating member ISL1 may include a first insulating layer ISL1-1, a second insulating layer ISL1-2, and a third insulating layer ISL1-3.

The first insulating layer ISL1-1 includes an organic layer, an inorganic layer or both. In particular, the first insulating layer ISL1-1 may include a plurality of inorganic thin layers. The plurality of inorganic thin layers may include a silicon nitride layer and a silicon oxide layer.

A control electrode GEP of the transistor TR is positioned on the first insulating layer ISL1-1.

A second insulating layer ISL1-2 covering the control electrode GEP may be positioned on the first insulating layer ISL1-1. The second insulating layer ISL1-2 includes an organic layer, an inorganic layer or both. In particular, the second insulating layer ISL1-2 may include a plurality of inorganic thin layers. The plurality of inorganic thin layers may include silicon nitride or silicon oxide.

A source line (not shown) and a power line (not shown) may be positioned on the second insulating layer ISL1-2. An input electrode SEP and an output electrode DEP of the transistor TR may be disposed on the second insulating layer ISL1-2.

The input electrode SEP and the output electrode DEP are respectively connected to the semiconductor layer ALP through a first through hole CH1 and a second through hole CH2 penetrating the first insulating layer ISL1-1 and the second insulating layer ISL1-2. In addition, in another embodiment of the present disclosure, the transistor TR may be modified to a bottom gate structure.

A third insulating layer ISL1-3 covering the input electrode SEP and the output electrode DEP may be positioned on the second insulating layer ISL1-2. The third insulating layer ISL1-3 includes an organic layer, an inorganic layer or both. In particular, the third insulating layer ISL1-3 may include an organic material to provide a flat surface.

A pixel insulating layer PXL and a light emitting element OLED may be positioned on the third insulating layer ISL1-3. An opening OP is defined in the pixel insulating layer PXL. The light emitting area PXA and the non-light emitting area NPXA may be divided by the pixel insulating layer PXL.

An anode AE is connected to the output electrode DEP through a third through hole CH3 penetrating the third insulating layer ISL1-3. The opening OP of the pixel insulating layer PXL exposes a portion of the anode AE. A hole control layer HCL may be commonly formed in the light emitting area PXA and the non-light emitting area NPXA. A light emitting layer EML and an electron control layer ECL are sequentially formed on the hole control layer HCL. Thereafter, a cathode CE may be commonly formed in the light emitting area PXA and the non-light emitting area NPXA. The cathode CE may be formed by deposition or sputtering according to a layer structure.

A thin film encapsulation layer TFE is disposed on the cathode CE. The thin film encapsulation layer TFE protects the light emitting element OLED from moisture and foreign substances.

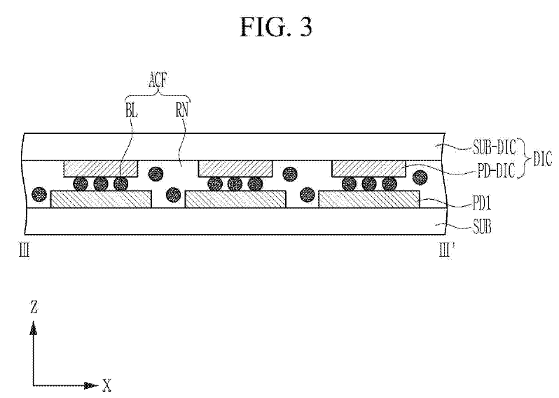

FIG. 3 shows a part of the first pad portion PDA1 and the integrated circuit DIC and is a cross-sectional view taken along line III-III' of FIG. 1.

A plurality of first electrode pads PD1 may be disposed on the substrate SUB of the display device 1 of FIG. 1. The plurality of first electrode pads PD1 may include metal.

The integrated circuit DIC may have pads PD-DIC disposed under a base member SUB-DIC. The base member SUB-DIC may be a silicon wafer, and the pads PD-DIC may include metal. Some of the pads PD-DIC may be short-circuited to each other.

A conductive adhesive layer ACF bonds the plurality of first electrode pads PD1 and the integrated circuit DIC. The conductive adhesive layer ACF may be an anisotropic conductive layer.

The conductive adhesive layer ACF may include a plurality of conductive balls BL and an insulating adhesive member RN.

Each of the plurality of conductive balls BL may be conductive fine particles. The conductive fine particles are capable of electrical conduction and may be conductive particles such as metals or metal oxides, or particles having an insulating material as a core and coated with metal or metal oxide on the surface. As the metal, nickel (Ni), iron (Fe), copper (Cu), aluminum (Al), tin (Sn), zinc (Zn), chromium (Cr), cobalt (Co), silver (Ag), or gold (Au) may be used.

The insulating adhesive member RN may include an insulating polymer. As the insulating polymer, for instance, epoxy resin, acrylic resin, and the like may be used.

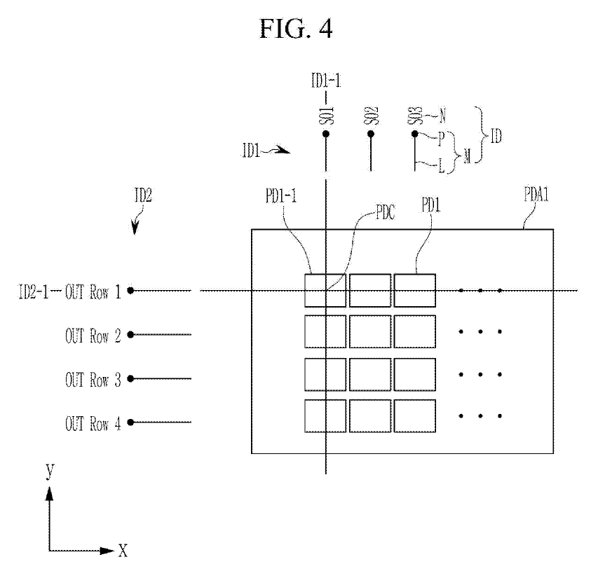

FIG. 4 shows a part of a first pad portion and its surrounding area of a display device according to an embodiment, and is an enlarged view of area A of FIG. 1. FIG. 4 shows that the integrated circuit DIC is not coupled in area A.

Referring to FIG. 4, a plurality of first electrode pads PD1 may be arranged in an x-axis direction x and a y-axis direction y inside the first pad portion PDA1. FIG. 4 shows that the plurality of first electrode pads PD1 are aligned in the x-axis direction x and the y-axis direction y.

Indicators ID may be positioned in an outer area of the first pad portion PDA1 on the non-display area NDA. The indicators ID may be positioned along a periphery of the first pad portion PDA1. The indicators ID may include first indicators ID1 disposed in an x-axis direction x and second indicators ID2 disposed in a y-axis direction y.

The indicators ID may specify positions of the plurality of first electrode pads PD1. A pair of indicators ID may be aligned with one first electrode pad PD1. That is, a pair of indicators ID may specify a position of one first electrode pad PD1. A pair of indicators ID may be defined as one first indicator ID1 and one second indicator ID2.

For instance, referring to FIG. 4, a first-first electrode pad PD1-1 may be aligned with a first-first indicator ID1-1 and a second-first indicator ID2-1. A position of the first-first electrode pad PD1-1 may be specified as a point where a line extending the first-first indicator ID1-1 in a y-axis direction y and a line extending the second-first indicator ID2-1 in an x-axis direction x meet.

Positions of the plurality of first electrode pads PD1 may be specified by a reference point PDC. The reference point PDC may be a center of the plurality of first electrode pads PD1. Also, it may be one of four vertices of the plurality of first electrode pads PD1.

The indicators ID include a marker M and an identifier N. The first indicators ID1 and the second indicators ID2 may each include a marker M and an identifier N.

The marker M may be a figure that can specify positions of the plurality of first electrode pads PD1. The marker M may include at least one of an indication line L and a dot P.

The first indicators ID1 may all have the same marker M. Similarly, the second indicators ID2 may all have the same marker M. Also, FIG. 4 shows that the first indicators ID1 and the second indicators ID2 all have the same marker M, but the first indicators ID1 and the second indicators ID2 may have different markers M.

The indication lines L of the first indicators ID1 may be straight lines extending in a y-axis direction, and the indication lines L of the second indicators ID2 may be straight lines extending in an x-axis direction. However, the indication lines L may not overlap the first pad portion PDA1 and may be spaced apart by a certain distance. The indication lines L may serve as guides for easily specifying positions of the plurality of first electrode pads PD1 positioned inside the first pad portion PDA1 using the indicators ID positioned outside the first pad portion PDA1.

The indication lines L of the first indicators ID1 may be aligned with reference points PDC of the plurality of first electrode pads PD1 in a y-axis direction y. The indication lines L of the second indicators ID2 may be aligned with reference points PDC of the plurality of first electrode pads PD1 in an x-axis direction x. For instance, a reference point PDC of a first-first electrode pad PD1-1 may be a point where a line extending from a first-first indicator ID1-1 extending in a y-axis direction y and a line extending from a second-first indicator ID2-1 extending in an x-axis direction x meet.

The dot P may be positioned at an end positioned far from the first pad portion PDA1 among two ends of the indication line L. In FIG. 4, the dot P is shown as circular, but is not limited thereto.

The identifier N may be a character that can distinguish a position of each of the plurality of first electrode pads PD1. The first indicators ID1 may have different identifiers N to distinguish positions of the plurality of first electrode pads PD1. Similarly, the second indicators ID2 may have different identifiers N.

The identifier N may include at least one of a letter and a number. For instance, the identifiers N of the first indicators ID1 may be displayed as S01, S02, S03, and the like, and the identifiers N of the second indicators ID2 may be displayed as OUT Row 1, OUT Row 2, OUT Row 3, OUT Row 4, and the like.

The identifier N is positioned adjacent to an end of the marker M and may be positioned adjacent to a dot P positioned at an end of the indication line L. The identifier N may be positioned farther from the first pad portion PDA1 than the marker M. The identifier N may be patterned in a direction in which the indication line L extends. That is, the identifiers N of the first indicators ID1 may be read along a y-axis direction y, and the identifiers N of the second indicators ID2 may be read along an x-axis direction x.

The indicators ID may be positioned around the first pad portion PDA1. The first indicators ID1 may be positioned above or below the first pad portion PDA1 in a y-axis direction y. The second indicators ID2 may be positioned to the left or right of the first pad portion PDA1 in an x-axis direction x. The indicators ID may be formed by patterning the substrate SUB with a laser and may be formed in a raised or recessed form with respect to a front surface of the substrate SUB.

The plurality of first electrode pads PD1 have rows arranged in an x-axis direction x and columns arranged in a y-axis direction y. FIG. 4 shows a case of 4 rows and 3 columns, and the number of rows and columns is not limited thereto. In an embodiment, a plurality of first electrode pads PD1 positioned in a same row are aligned with a same second indicator ID2 in an x-axis direction x, and a plurality of first electrode pads PD1 positioned in a same column may be aligned with a same first indicator ID1 in a y-axis direction y.

The indicators ID are spaced apart from not only the first pad portion PDA1 but also the integrated circuit DIC of FIG. 1. The indicators ID are not covered by the integrated circuit DIC and may be visible from the front of the display device 1. Therefore, even in case that the substrate is opaque, positions of each of the plurality of first electrode pads PD1 may be specified by the indicators ID. Referring to FIGS. 1 and 3 together, in case that the substrate SUB of the display device 1 and the base member SUB-DIC of the integrated circuit DIC are silicon wafers, the first electrode pads PD1 are not visible from the front, but positions of the plurality of first electrode pads PD1 may be specified by the indicators ID. Therefore, even in case that the integrated circuit DIC is coupled, a position of a defective pad may be specified by the indicators ID to perform cross-sectional analysis and detect a defect.

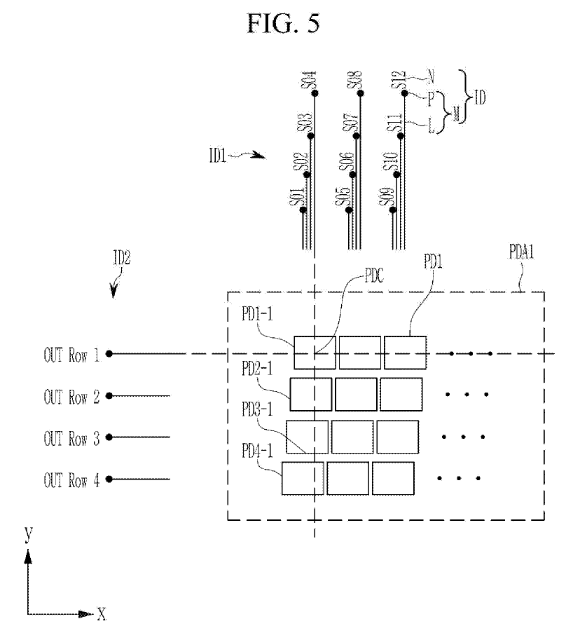

FIGS. 5 to 7 show a first pad portion and a part of its surrounding area of a display device according to embodiments, and are views corresponding to an enlarged portion of area A of FIG. 1.

FIGS. 5 to 7 show that the integrated circuit DIC is not bonded to area A of FIG. 1. Descriptions of configurations redundant to those of FIG. 4 are omitted.

Referring to FIGS. 5 to 7, a plurality of first electrode pads PD1 may be arranged in an x-axis direction x and a y-axis direction y inside the first pad portion PDA1. FIGS. 5 to 7 show that the plurality of first electrode pads PD1 are aligned in the x-axis direction x but not aligned in the y-axis direction y. The plurality of first electrode pads PD1 are shifted from each other in the y-axis direction y.

FIGS. 5 to 7 show only 4 rows and 3 columns of the plurality of first electrode pads PD1, and are not limited thereto. Also, it is shown that a plurality of first electrode pads PD1 positioned in a same row are aligned with a same second indicator ID2, and a plurality of first electrode pads PD1 positioned in a same column are aligned with different first indicators ID1. According to an embodiment, a plurality of first electrode pads PD1 positioned in a same row may be aligned with different second indicators ID2, and a plurality of first electrode pads PD1 positioned in a same column may be aligned with a same first indicator ID1. Also, a plurality of first electrode pads PD1 positioned in a same row may be aligned with different second indicators ID2, and a plurality of first electrode pads PD1 positioned in a same column may be aligned with different first indicators ID1.

Referring to FIG. 5, first indicators ID1 aligned with a plurality of first electrode pads PD1 in a same column may include indication lines L of different lengths. For instance, lengths of indication lines L of first indicators ID1 aligned with a first electrode pad PD1-1 positioned in row 1, column 1, a first electrode pad PD2-1 positioned in row 2, column 1, a first electrode pad PD3-1 positioned in row 3, column 1, and a first electrode pad PD4-1 positioned in row 4, column 1 may sequentially increase.

The identifier N is positioned adjacent to an end positioned far from the first pad portion PDA1 among two ends of the indication line L and may be patterned in a direction in which the indication line L extends. That is, the identifiers N of the first indicators ID1 may be read in a y-axis direction y, and the identifiers N of the second indicators ID2 may be read in an x-axis direction x.

By making the lengths of the indication lines L different from each other, space for the identifiers N positioned at the ends of the indication lines L may be secured. Therefore, the space of the non-display area NDA (see FIG. 1) may be efficiently utilized.

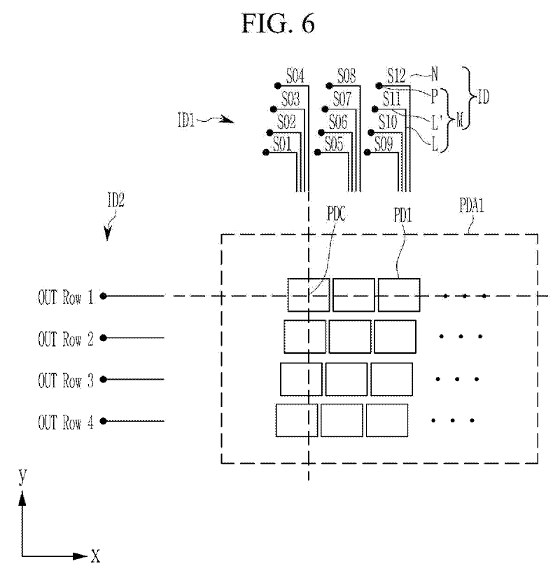

Referring to FIG. 6, the marker M of the first indicators ID1 may further include an auxiliary line L' positioned at an end of the indication line L and perpendicular to the indication line L. The auxiliary line L' may be connected to an end far from the first pad portion PDA1 among two ends of the indication line L. In the embodiment of FIG. 6, the auxiliary line L' of the first indicators ID1 extends in an x-axis direction x and may be shorter than the indication line L. A dot P may be further positioned at an end of the auxiliary line L'.

The identifier N may be patterned on an upper portion of the auxiliary line L' along a direction in which the auxiliary line L' extends. That is, in the embodiment of FIG. 6, the identifier N of the first indicator ID1 may be read in an x-axis direction x on the auxiliary line L'.

By including the auxiliary line L' orthogonal to the indication line L, a space where the identifier N is patterned may be secured and at the same time the space occupied by the indicators ID may be reduced. Therefore, the space of the non-display area NDA (see FIG. 1) may be efficiently utilized.

FIG. 6 shows that only the first indicators ID1 include the auxiliary line L', but according to an embodiment, the second indicators ID2 may also include the auxiliary line L'.

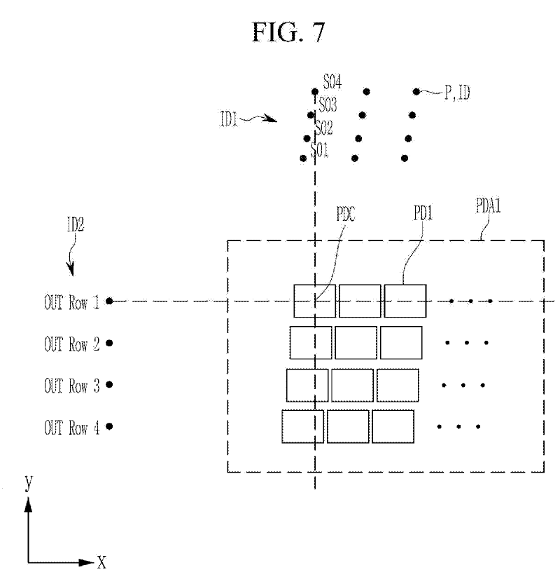

Referring to FIG. 7, the indicators ID may not include the indication line L and may consist of dots P. For instance, a point where a line extending from a dot P of a first indicator ID1 in a y-axis direction y and a line extending from a dot P of a second indicator ID2 in an x-axis direction x meet may be a reference point PDC of a first electrode pad PD1.

By not including the indication line L in the indicators ID, a space where the identifier N is patterned may be secured and the space occupied by the indicators ID may be reduced. Therefore, the space of the non-display area NDA (see FIG. 1) may be efficiently utilized.

Referring to FIGS. 4 to 7 together with FIG. 1, the indicators ID may be visible from the front of the display device 1 even in case that the substrate SUB and the integrated circuit DIC are opaque. Therefore, a position of a defective electrode pad may be specified by the indicators ID to perform cross-sectional analysis and detect a defect.

For instance, a first indicator ID1 and a second indicator ID2 aligned to a defect position may be specified through a driving program. A point where a line extending the specified first indicator ID1 in a y-axis direction y and a line extending the specified second indicator ID2 in an x-axis direction x meet may be a defect position.

The defect position may be processed by grinding or cut by a Focused Ion Beam (FIB), and a cross section may be analyzed by SEM (Scanning Electron Microscopy) or TEM (Transmission Electron Microscopy).

As described above, by using the indicators ID, destructive analysis may be easily performed on the display device 1 comprising the opaque substrate SUB and the integrated circuit DIC.

The display device according to the embodiment may be applied to various electronic devices. An electronic device according to an embodiment includes the above-described display device and may further include a module or device that provides additional functions besides the display device.

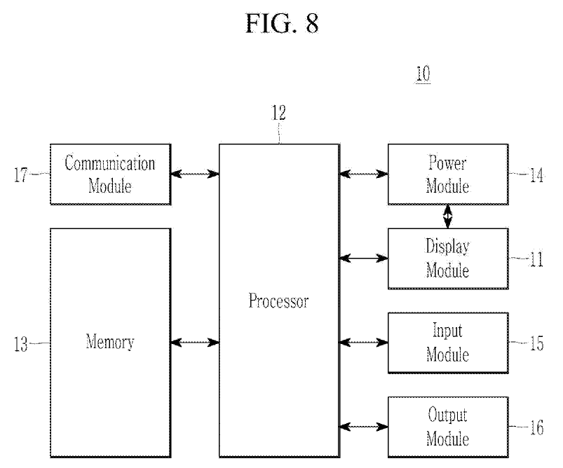

FIG. 8 is a block diagram of an electronic device according to an embodiment. Referring to FIG. 8, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. The processor 12 may be implemented by one or more processors and collectively the one or more processors may be referred to as a processor.

The memory 13 may store data information desirable for the operation of the processor 12 or the display module 11. In the case that the processor 12 executes an application stored in the memory 13, an image data signal, an input control signal or both are transmitted to the display module 11, and the display module 11 processes the received signal to output image information through a display screen.

The power module 14 may include a power supply module such as a power adapter or a battery device and a power conversion module that converts power supplied by the power supply module to generate power desirable for the operation of the electronic device 10.

The electronic device 10 may further include an input module 15, a non-image output module 16, and a communication module 17.

The input module 15 may provide input information to the processor 12 and the display module 11. The input module 15 may include physical buttons, a keyboard, a microphone, as well as various sensor modules. Cases of sensor modules may include a touch sensor, a pressure sensor, a distance sensor, a position sensor, a digitizer, a motion recognition sensor, a camera sensor, a light receiving sensor, a photoelectric conversion sensor, a temperature sensor, as well as biometric sensors such as a blood pressure sensor, a blood glucose sensor, an electrocardiogram sensor, and a heart rate sensor.

The non-image output module 16 may receive information other than images transmitted from the processor 12 and provide it to a user. Cases of the non-image output module 16 include an acoustic module, a haptic module, a light emitting module, and may include other function modules unique to electronic devices (for instance, a cooling module of a refrigerator).

The communication module 17 is a module responsible for transmitting and receiving information between the electronic device 10 and an external device and may include a receiver and a transmitter. The communication module 17 may include various wireless communication modules such as a mobile communication module, a Wi-Fi module, and a Bluetooth module, or various wired communication modules.

At least one of the components of the above-described electronic device 10 may be included in the display device according to the above-described embodiments. Also, some of the individual modules functionally included in a single module may be included in the display device, and others may be provided separately from the display device. For instance, the display device includes the display module 11, and the processor 12, the memory 13, and the power module 14 may be provided in the form of other devices in the electronic device 10 rather than the display device.

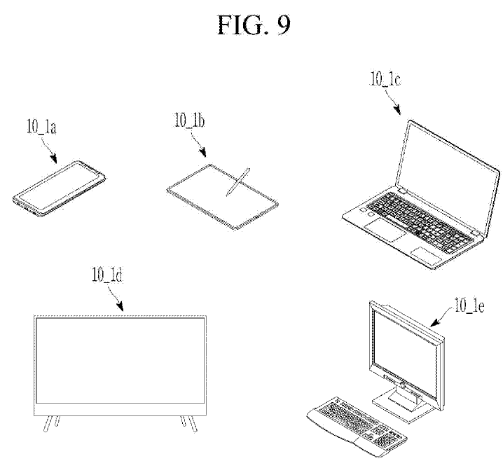

FIGS. 9 to 11 are schematic diagrams of electronic devices according to various embodiments. FIGS. 9 to 11 show cases of various electronic devices to which the display device according to the embodiments is applied.

FIG. 9 shows a smartphone 10_1a, a tablet PC 10_1b, a laptop 10_1c, a TV 10_1d, and a desktop monitor 10_1e as cases of electronic devices.

The smartphone 10_1a may include an input module such as a touch sensor and a communication module in addition to the display module 11. The smartphone 10_1a may process information received through the communication module or other input modules and display information through the display module of the display device.

The tablet PC 10_1b, laptop 10_1c, TV 10_1d, and desktop monitor 10_1e also include a display module and an input module similar to the smartphone 10_1a, and may further include a communication module in some cases.

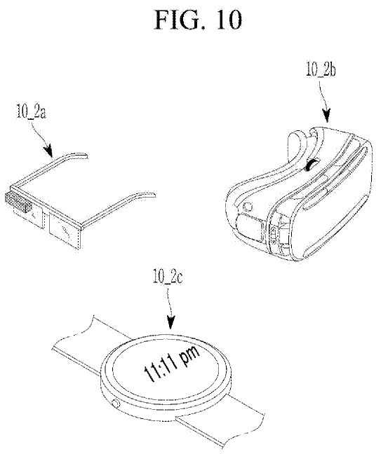

FIG. 10 illustrates a case where an electronic device comprising a display module is applied to a wearable electronic device. The wearable electronic device may be smart glasses 10_2a, a head-mounted display 10_2b, a smart watch 10_2c, or the like.

The smart glasses 10_2a and the head-mounted display 10_2b may include a display module that emits display images and a reflector that reflects the emitted display screen and provides it to the user's eyes, thereby providing the user with a virtual reality or augmented reality screen.

The smart watch 10_2c includes a biometric sensor as an input device and may provide biometric information recognized through the biometric sensor to a user through a display module.

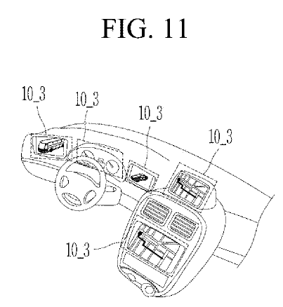

FIG. 11 illustrates a case where an electronic device comprising a display module is applied to a vehicle. For instance, the electronic device 10_3 may be applied to an instrument panel, center fascia, and the like of a car, or to a CID (Center Information Display) disposed on a dashboard of a car or a room mirror display that replaces a side mirror.

Although not shown, electronic devices to which the display device according to the embodiments is applied may include not only devices mainly for screen display such as billboards, electronic signs, and game consoles, but also various home appliances that display information through display modules such as refrigerators, washing machines, dryers, air conditioners, and robot vacuum cleaners. Also, in case that the display module has a function of transmitting light, it may be applied to electronic devices such as smart windows or transparent display devices that display background and display images together. The types of electronic devices according to the embodiments are not limited by the above cases, and applications to various other electronic devices not disclosed may be possible.

Although the embodiments of the present disclosure have been described in detail above, the scope of the present disclosure is not limited thereto, and various modifications and improvements by those skilled in the art using the basic concept of the present disclosure defined in the following claims also belong to the scope of the present disclosure.

What is claimed is:

1. A display device comprising:
a substrate comprising a display area and a non-display area;
a pad portion positioned on the non-display area and comprising a plurality of electrode pads; and
indicators positioned along a periphery of the pad portion on the non-display area and specifying positions of the plurality of electrode pads.

2. The display device of claim 1, wherein the plurality of electrode pads are arranged in an x-axis direction and a y-axis direction crossing each other, the indicators include first indicators disposed in the x-axis direction and second indicators disposed in the y-axis direction, and the plurality of electrode pads are aligned with the first indicators and the second indicators.

3. The display device of claim 2, wherein positions of the plurality of the electrode pads are points where lines extending from the first indicators in the y-axis direction and lines extending from the second indicators in the x-axis direction meet.

4. The display device of claim 3, wherein the plurality of electrode pads have rows arranged in the x-axis direction and columns arranged in the y-axis direction, the plurality of electrode pads positioned in a same row are aligned with a same second indicator, and the plurality of electrode pads positioned in a same column are aligned with a same first indicator.

5. The display device of claim 3, wherein the plurality of electrode pads have rows arranged in the x-axis direction and columns arranged in the y-axis direction, the plurality of electrode pads positioned in a same row are aligned with a same second indicator, and the plurality of electrode pads positioned in a same column are aligned with different first indicators.

6. The display device of claim 2, wherein the first indicators and the second indicators each include a marker and an identifier.

7. The display device of claim 6, wherein the identifier is characters for distinguishing a position of each of the plurality of electrode pads and includes at least one of an alphabetic character and a number.

8. The display device of claim 7, wherein the identifier is positioned adjacent to an end of the marker.

9. The display device of claim 6, wherein the marker includes at least one of a dot and an indication line.

10. The display device of claim 9, wherein the marker includes the indication line, indication lines of the first indicators extend in the y-axis direction and are aligned with reference points of the plurality of electrode pads in the y-axis direction, and indication lines of the second indicators extend in the x-axis direction and are aligned with reference points of each of the plurality of electrode pads in the x-axis direction.

11. The display device of claim 10, wherein the reference point is a center of the plurality of electrode pads.

12. The display device of claim 10, wherein at least one of the indication lines of the first indicators and the indication lines of the second indicators includes an auxiliary line connected to an end of the at least one of the indication lines and perpendicular to the at least one of the indication lines, and the identifier is positioned along the auxiliary line.

13. The display device of claim 10, wherein the marker includes a dot positioned at an end of the indication line.

14. The display device of claim 9, wherein the marker includes a dot, dots of the first indicators are aligned with centers of the plurality of electrode pads in a y-axis direction, and dots of the second indicators are aligned with centers of the plurality of electrode pads in an x-axis direction.

15. The display device of claim 2, wherein the first indicators are positioned above or below the pad portion in the y-axis direction, and the second indicators are positioned to the left or right of the pad portion in the x-axis direction.

16. The display device of claim 1, wherein the indicators are in a raised or recessed form with respect to a front surface of the substrate.

17. The display device of claim 1, wherein the substrate is a silicon wafer substrate.

18. The display device of claim 1, further comprising an integrated circuit positioned on the pad portion and coupled to the plurality of electrode pads.

19. An electronic device comprising:
a display device, a processor, a memory, and a power module,
wherein the display device comprises:
a substrate comprising a display area and a non-display area;
a pad portion positioned on the non-display area and comprising a plurality of electrode pads; and
indicators positioned along a periphery of the pad portion on the non-display area and specifying positions of the plurality of electrode pads.

20. The electronic device of claim 19, wherein the plurality of electrode pads are arranged in an x-axis direction and a y-axis direction crossing each other, the indicators include first indicators disposed in the x-axis direction and second indicators disposed in the y-axis direction, and the plurality of electrode pads are aligned with the first indicators and the second indicators.
